(19) United States
(12) Patent Application Publication
(10) Pub. No.: US 2026/0221849 A1
(43) Pub. Date: Jul. 30, 2026

(54) ELECTRIC MOTOR COMPRISING A POWER ELECTRONICS-CARRYING CIRCUIT BOARD AND A COOLING PLATE

(71) Applicant: Innomotics GmbH, 90441 Nürnberg (DE)

(72) Inventor: Frank BRÜTTING, Erlangen (DE)

(73) Assignee: Innomotics GmbH, 90441 Nürnberg (DE)

(21) Appl. No.: 19/151,894

(22) PCT Filed: Jan. 12, 2024
(86) PCT No.: PCT/EP2024/050638

§ 371 Date: Jul. 29, 2025

(30) Foreign Application Priority Data
Jan. 30, 2023 (EP) 23153972.7

(51) Int. Cl. H02K 11/33; H02K 9/22; H05K 1/02

(52) U.S. Cl. CPC H02K 11/33; H02K 9/223; H02K 9/227; H05K 1/0201; H02K 2211/03; H05K 2201/064; H05K 2201/10598

(57) ABSTRACT

An electric motor includes a stator having a plurality of bar-shaped field conductors. A cooling plate is arranged such that the field conductors are mechanically operatively connected to the cooling plate via current conductors that are electrically connected to the field conductors. The cooling plate is segmented into at least two sub-segments, which are electrically insulated from one another and annular or designed in a form of annular sectors. A separating surface between the sub-segments represents less than 20% of a cooling surface. A printed circuit board structure having one or more printed circuit boards, with at least one of the printed circuit boards being arranged on the cooling plate. The printed circuit boards are electrically contacted to the sub-segments of the cooling plate in order to supply power. A plurality of power electronics components controls the field conductors and is arranged on the printed circuit board structure.

The invention relates to an electric motor comprising a stator-side bar winding.

Electric motors can have a bar winding on the stator side. The stator has a series of bars instead of wound wire conductors as field conductors. As compared with conventional windings, the bars have a low inductance. Therefore, a comparatively high current flow is required for the production of a predefined magnetic field. A motor of this design is described in EP 19167289 A1.

However, because of the low resistance of the bars, this high current flow needs only a comparatively low voltage of, for example, 12 V. The low voltage permits the components of the inverter with which the bars are controlled to be arranged at short distances from one another. Thus, the components of the power electronics can be arranged, for example, on one or more printed circuit boards, which are arranged close to (preferably in the housing of) the electric motor. The bars can be used as mechanical supports of the printed circuit boards, directly or via electrically conductive bar-like connecting elements.

The printed circuit boards are mounted on cooling plates and contacted individually via electric busbars. The busbars rest on the printed circuit boards and are contacted by the latter via screw connections. The screw connections are, however, also fastened in the cooling plates (mechanically decoupled from the latter), in order to produce a reliable contact. In each case this results in the problem of the insulation between the screw connection and the cooling plate, which must be solved for each individual screw connection by means of an appropriate sleeve.

In particular when a printed circuit board has to be replaced because of defective individual components, the busbars—as a rule two busbars—which span up to 150 printed circuit boards and supply them with power, have to be unscrewed and then be completely insulated and screwed up again.

The invention is based on the object of providing an electric motor comprising a stator-side bar winding and integrated power electronics which, as compared with the prior art, requires less outlay on repairs during the replacement of printed circuit boards of the power electronics.

The object is achieved by an electric motor having the features of patent claim 1.

This electric motor comprises
a stator having a plurality of field conductors in the form of bars,
a plurality of power electronics components for controlling the field conductors, wherein
the power electronics components are arranged on one or more printed circuit boards, and
at least one printed circuit board, which is arranged on at least one cooling plate,
wherein the cooling plate is arranged such that the field conductors are mechanically operatively connected to the cooling plate via current conductors that are electrically connected to the field conductors. (This can be done by means of through holes through the cooling plate. The mechanical operative connection can, however, also be made indirectly to the cooling plate, for example via holes in the printed circuit boards, wherein the printed circuit boards on these holes project partly over the edge of the cooling plate). Accordingly, the current conductors form current-conducting connecting elements between the field conductors and the printed circuit boards and ultimately to the power electronics components (also semiconductor switches), Because of the mechanical operative connection, these also have a supporting property for the cooling plate, being insulated electrically with respect thereto.
The invention is distinguished by the fact that
the cooling plate is segmented into at least two sub-segments 16-1, 16-2 which are electrically insulated from one another,
wherein a separating surface 20 between the sub-segments 16-1, 16-2 represents less than 20% of a cooling surface 22, and
the printed circuit boards 15 are electrically contacted with the sub-segments 16-1, 16-2 of the cooling plate 16 in order to supply power.

The power supply of the electric motor is accordingly firstly provided by the sub-segments of the cooling plate(s) to the printed circuit boards and the power electronics components arranged thereon and onward from the latter via the current conductors to the field conductors of the stator.

The electric motor described differs from conventional electric motors in that the stator has a series of bars instead of wound wire conductors as field conductors. As compared with conventional windings, the bars have a low Inductance. Therefore, a comparatively high current flow is required for the production of a predefined magnetic field.

Fundamental advantages in the operation of the machine result from the structure of the bar winding: as a result of the segmented controllability of the magnetic flux between each two field conductors, far more flexible forms of magnetic fields can be impressed into the machine than would be possible with a distributed winding and its inherent superimposition effects. This results in many (control) advantages with regard to the running properties of the machine. Furthermore, the failure of a phase ((of the control) of a field conductor) has far less significant consequences than would be the case, for example, in a double-three-phase or even normal three-phase machine. Since these effects can additionally be very well compensated by the adjacent phases, with each phase failure and given appropriate stabilization, the drive power decreases virtually exclusively by only a small fraction without having any noticeable influence on the remaining properties.

The advantage with the electric motor described as compared with the prior art of motors of this design consists in the fact that the busbars are not arranged on the printed circuit boards, instead the cooling plate itself ensures the power supply of the printed circuit boards. In this way, each printed circuit board can be removed and replaced individually by loosening the screw fixing which, as a rule, also represents the contact with the busbars, without great effort. Thus, for a repair, it is therefore not necessary for large parts or even the entire structure of all the printed circuit boards to be broken down, which, during repair work on the power electronics, signifies a considerable saving in the working effort and thus represents a cost advantage. The repair costs are reduced considerably.

Furthermore, as a result of this constructional configuration, which consists in dividing the cooling plate into at least two segmented portions and using it for contacting and thus for supplying power, the fact is, firstly, that the mounting of the printed circuit boards is not hampered but, at the same time, the entire contact surface of the printed circuit boards on the cooling plate can also be used as a cooling surface. A relatively large electric contact surface for the DO supply (instead of a smaller contact surface to corresponding DO railings) is likewise advantageous. Although a metallic bust which is countersunk in a cooling plate is in principle also thermally conductive, it develops no cooling action, since it is electrically and therefore largely thermally insulated with respect to the cooling plate (this insulation is likewise generally advantageously omitted). Therefore, following the heating of the busbar, there is no noticeable dissipation of heat from the latter, and thus it does not act as a cooling plate.

The term cooling surface is defined as the surface on which the printed circuit board lies at least indirectly flat. If appropriate, it may be expedient for technical reasons, for example for additional electrical insulation or for mechanical damping, to arrange an intermediate layer or film between the printed circuit board and cooling plate. In this connection, it is also viewed as the printed circuit board resting flat on the cooling surface, since the cooling surface provides for the absorption of heat from the printed circuit board. The separating surface is the surface which, when the cooling plate is viewed vertically, is arranged between the sub-segments of the cooling plate and which is used for the electrical insulation between the sub-segments of the cooling plate.

Here, it is necessary to take into account that, in general for the motor described, it is not necessarily exactly two current-carrying potentials that are used. It is also advantageous to use duplicate potentials or, for example, three potentials with an intermediate circuit center point or dual (redundant) intermediate circuits, more than two current conductors being needed.

In one embodiment of the invention, contact is made with the printed circuit board at contact points by means of a fastening means on the cooling plate. The fastening means can preferably be a screw fixing. As a result of the contacting by means of a fastening means, two necessary requirements, namely making contact and the fastening between the cooling plate and printed circuit board, can be made with one device, which additionally saves technical effort. In addition to a screw fixing for the contacting, snap fasteners or clamping connections would also be expedient,

Furthermore, it is advantageous if the cooling plate 16 is thermally connected to a heat sink 38. Thus the heat which Is conducted from the components into the cooling plate via the printed circuit boards can once more be dissipated easily. Particularly preferably, the heat sink is configured in the form of a cooling conduit, which in turn preferably runs through the cooling plate in a horizontal plane relative to the cooling surface.

The sub-segments of the cooling plate are also preferably annular or in the form of an annular sector. In this way, a good combination of good contactability of the printed circuit boards and good heat dissipation can be achieved. It is additionally advantageous if the cooling plate is formed from aluminum or copper or from an alloy of these metals.

The printed circuit boards can be configured in the form of a circular or annular sector. Printed circuit boards having this shape can be assembled to form a circle or ring and thus, matched optimally to the shape of the electric machine, arranged at an axial end of the machine, high modularity being achieved at the same time.

The terms “axial”, “radial” and “tangential” refer to the axis of the rotor and therefore to the corresponding axis of symmetry of the stator. “Axial” describes a direction parallel to this axis, “radial” describes a direction orthogonal to the axis, toward or else away from it, and “tangential” is a direction which is directed circularly around the axis at a constant radial distance from the axis and with a constant axial position. The expression “in the circumferential direction” is to be equated with “tangential”.

If the terms “axial”, “radial” and “tangential” are used in relation to a surface, for example a cross-sectional surface, the terms describe the orientation of the normal vector to the surface, i.e. that vector which is vertical to the surface involved.

Further embodiments of the invention and further features will be explained in more detail by using the following figures. These are purely schematic embodiments which do not represent any restriction to the protective scope.

In the figures:

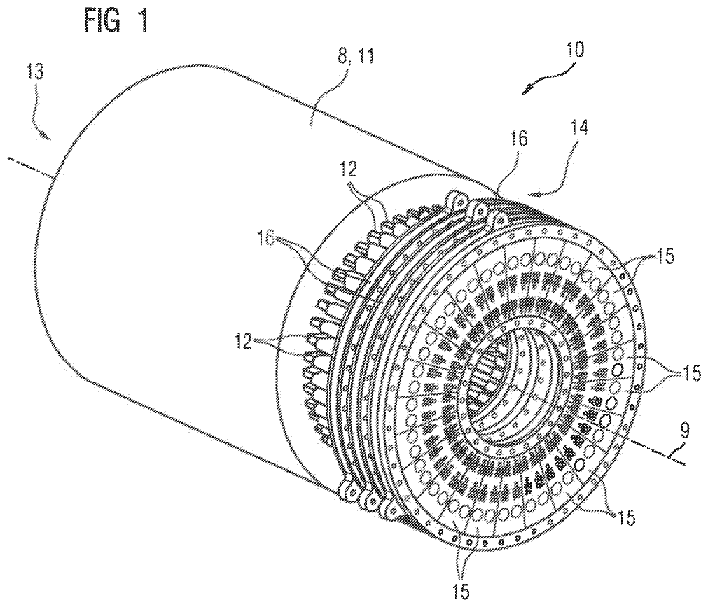

FIG. 1 shows an electric motor having cooling plates for cooling printed circuit boards in a side view,

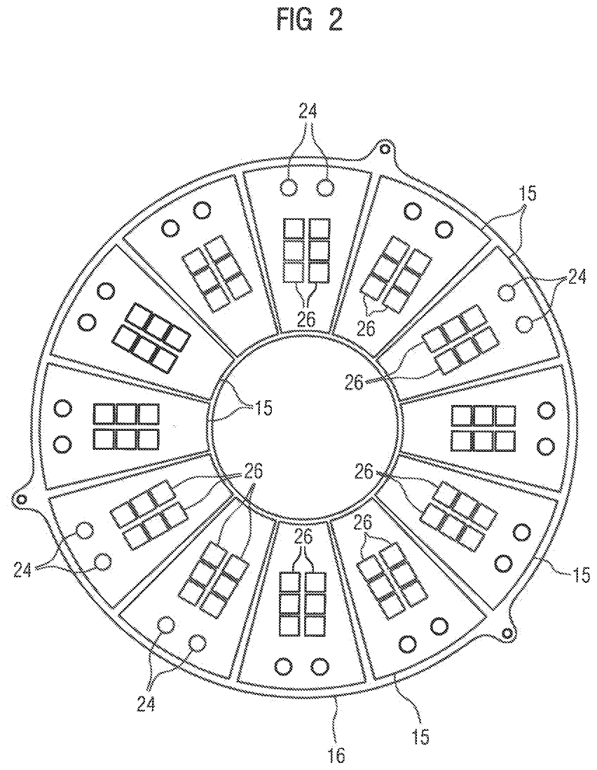

FIG. 2 shows the electric motor in front view,

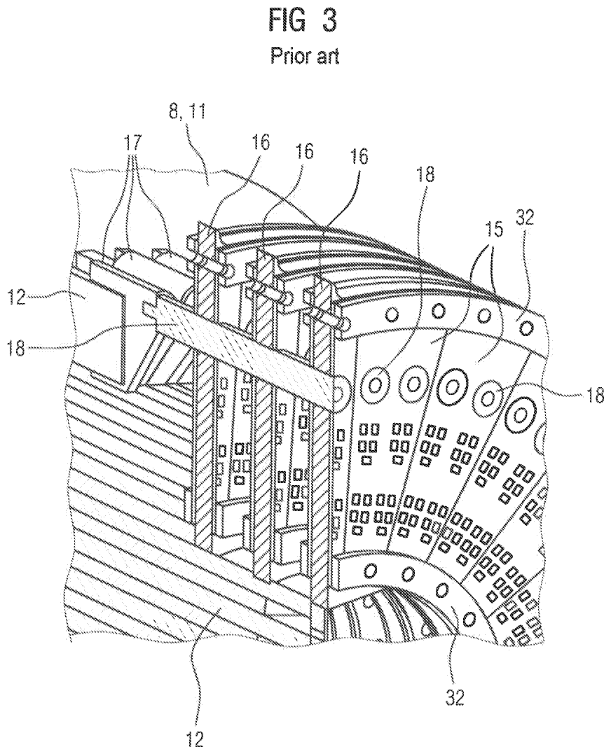

FIG. 3 shows an enlarged Illustration of FIG. 1 in a detail of the cooling plates in a side view with busbars according to the prior art.

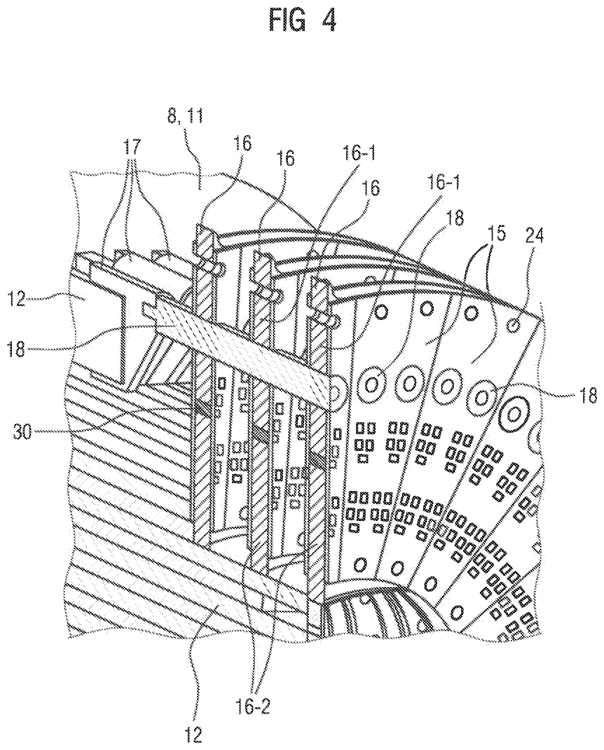

FIG. 4 shows the same detail as in FIG. 3 with a modified arrangement of the power supply,

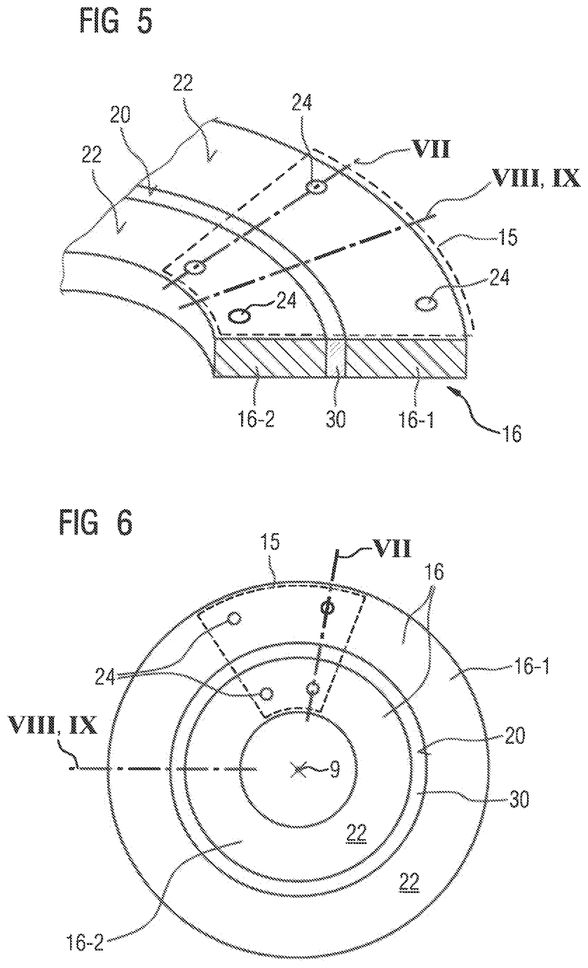

FIG. 5 shows a three-dimensional cross section and detail of a cooling plate with the printed circuit board indicated,

FIG. 6 shows a plan view of a cooling plate with the printed circuit board indicated,

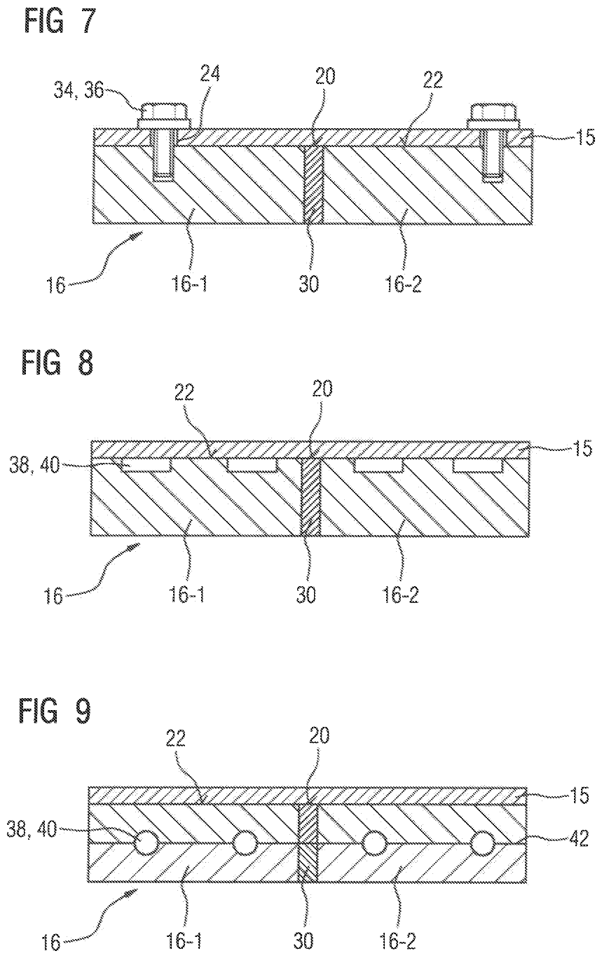

FIG. 7 shows a cross section through a cooling plate through a screw fixing,

FIG. 8 shows a cross section through a cooling plate with surface cooling conduits,

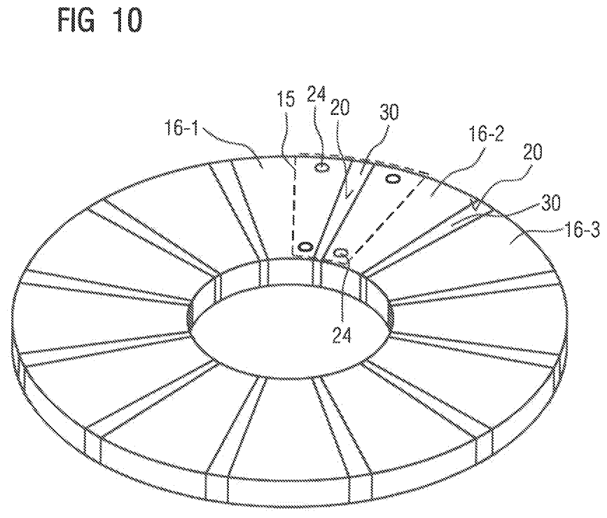

FIG. 9 shows a cross section through a cooling plate with centrally arranged cooling conduits, and

FIG. 10 shows a three-dimensional illustration of a cooling plate with sub-segments configured in the shape of annular segments.

FIG. 1 illustrates an isometric view of an electric motor 10 which is an exemplary embodiment of the invention. The electric motor 10 comprises a stator 11 and a rotor which is arranged substantially in the stator 11 but is not visible in FIG. 1. The rotor is co-rotationally connected to a shaft, which is likewise not Illustrated in FIG. 1. As a result of electromagnetic Interaction of the rotor with an energized stator 11, the rotor is set rotating about an axis 9. The rotor is separated from the stator 11 by an air gap.

In other embodiments, the electric motor 10 can also be an external rotor motor or bell-type armature motor,

The stator 11 comprises a plurality of rigid and straight conductor bars 12 as field conductors. These conductor bars 12 are connected to one another via a short-circuit ring on the end face 13 facing away in FIG. 1. On the rear side 14 of the electric motor 10, the conductor bars 12 are fed individually by respective associated inverter modules. Since, as a result of the conductor bars 12, this is an electric motor 10 operated at low voltages, the inverter modules can be arranged relatively close together on the printed circuit boards 15 together with other components of the electronics (DC converters, rectifiers). The printed circuit boards 15 in this example are in the form of annular sectors, and many individual printed circuit boards 15 together form an annular printed circuit board structure. The rigidly formed conductor bars can be formed from a metallic bar, for example a copper bar, or by means of a solid multifilament conductor.

While it is assumed in the examples that the printed circuit boards 15 carry inverter modules, it is also possible for some of the printed circuit boards 15 to carry rectifiers and DC/DC converters.

FIG. 2 shows a plan view of such a printed circuit board structure. The number of printed circuit boards 15 Illustrated in FIG. 2 is reduced with respect to the illustration in FIG. 1 for improved clarity and is illustrated in a highly simplified manner. The actual number of such printed circuit boards 15 depends on the practical configuration of the electric motor 10, in particular the number of conductor bars 12. Each of the printed circuit boards 15 comprises a plurality of power electronics components, in particular semiconductor switches 26.

Furthermore, some of the printed circuit boards 15 or all of the printed circuit boards 15 can comprise driver circuits and other electronic components such as capacitors, not illustrated in the figures. The semiconductor switches 26 are power semiconductors such as, for example, IGBTs, MOSFETs or JFETs and can additionally comprise diodes, not shown, depending on the wiring. The semiconductor switches 26 are, for example, wired as half-bridges. A capacitor, not shown, can for example represent an intermediate circuit capacitor of the half-bridges. The semiconductor switches 26 of a printed circuit board 15 can be assigned to an individual phase or to a plurality of phases.

Since, as compared with conventional motors with windings, comparatively high currents are necessary in the conductor bars in the electric motor 10, a plurality of inverters are preferably connected in parallel for their energization. This can be achieved, for example, by the six printed circuit board structures shown in FIG. 1 on three cooling plates 16 all being connected identically to the conductor bars 12 and thus attached electrically in parallel. Use is made of the fact that the conductor bars 12 or connecting elements 18 to the conductor bars 12 penetrate the cooling plates 16 and therefore also the printed circuit boards 15 identically at the contact points or, in the case of the outermost cooling plate 16, at least contact the same.

FIG. 3 shows a sectional image of the electric motor 10 in an oblique view. It can be seen here that the connecting elements 18 mechanically support and penetrate the three cooling plates 16. This can also be done indirectly by the printed circuit boards 15 projecting radially beyond the cooling plates 16 and the connecting elements penetrating the printed circuit boards in the projecting areas. The connecting elements 18 are connected to the conductor bars 12 via shoes 17. The inverters, which are located on the printed circuit boards 16 in the areas in which one of the connecting elements 18 penetrates a cooling plate 16, are connected in parallel and together provide the power for the conductor bar 12.

In FIG. 3, busbars 32 in the embodiment according to the prior art are also illustrated. These are screwed onto the printed circuit boards 15 and therefore fasten these to the cooling plate 16. Then, if a printed circuit board 15 is defective and must be replaced, the busbars 32 with all the individual screw fixings to the printed circuit boards 15 have to be removed. This means that, for example, in the case of 100 printed circuit boards 15 each having three screw fixings, 300 screw fixings have to be released. This outlay is reduced by the configuration according to FIG. 4 and subsequently illustrated schematically and enlarged in FIGS. 5 to 10.

In FIG. 4, the same arrangement as in FIG. 3 with respect to the arrangement of the cooling plates 16 with respect to the electric motor 10 and the motor axis 9 is illustrated, but the contacting of the printed circuit boards 15 is carried out by sub-segments 16-1 and 16-2 of the cooling plate 16.

In FIG. 5, a cross section and a detail from a cooling plate 16 as arranged in FIG. 4, for example, is now shown. This cooling plate 16 is divided into two sub-segments, a first sub-segment 16-1 and a second sub-segment 16-2. The two sub-segments 16-1 and 16-2 are insulated electrically from one another by Insulation 30. If the cooling plate 16 is viewed at right angles to the motor axis 9, the sub-segments 16-1 and 16-2 and the insulation 30 thus form a flat surface. The surfaces of the sub-segments 16-1 and 16-2 form a cooling surface 22. In the plan view, this cooling surface 22 is subdivided by a separating surface 20, which is formed by the insulation 30. For advantageous dissipation of the amount of heat which is input from the printed circuit boards 15, it is expedient if the area of the separating surface 20 is as small as possible; it should represent at most 20% of the area of the cooling surface 22. Particularly advantageously, the separating surface 20 should represent less than 10%, particularly advantageously less than 5%, of the cooling surface 22.

In FIGS. 5 and 6, the positioning of a printed circuit board 15 is Indicated by a dashed line. Furthermore, contact points 24 are also shown, via which electrical contact is made between the current-conducting cooling plate 16 and the printed circuit board 15, and the power electronics components arranged thereon.

In FIGS. 5 and 6, the sub-segments 16-1 and 16-2 are configured in the form of two concentric rings. In principle, it should be pointed out that other possible segmentation on the cooling plate 16 may be expedient, for example as Illustrated in FIG. 10. In FIG. 10, the sub-segments 16-1, 16-2, 16-3 are subdivided into units in the shape of annular segments. They have a similar geometric configuration to the way in which the printed circuit boards 15 are usually and advantageously configured. It may be expedient for the printed circuit boards 15 to each overlap two sub-segments 16-1 to 16-2 in such a way that, as indicated in FIG. 10, contact is made with a respective sub-segment having a different electric potential. It should be noted that, depending on the electrical wiring, even in the case of a DC supply of the printed circuit boards, a plurality of current-conducting contacts with different potentials may be expedient and/or necessary.

The cooling plate 16, which is segmented into its sub-segments 16-1, 16-2 and/or 16-3, is preferably formed from aluminum or an aluminum alloy or from copper or a copper alloy. These metals are easy to fabricate, conduct current very well and have a high thermal conductivity. Thus, the cooling plate can perform its function both as a current conductor and as a cooling body. The insulation 30, on the other hand, is preferably configured from an insulating plastic. The insulation 30 can also at least partly be configured as an empty space, in which air functions as an insulating medium.

In FIGS. 7 to 9, cross-sectional illustrations through the cooling plate 16 illustrated in FIG. 6 and FIG. 5 are provided and are identified there by the sections VII, VIII and IX. In FIG. 7, in addition to the sections through the sub-segments 16-1 and 16-2, which are separated from one another by the insulation 30 and which together form the cooling plate 16, the fastening of the printed circuit board 15 to the cooling plate 16 is illustrated schematically. A fastening means 34, which is configured In the form of a screw fixing 36, is provided at a contact point 24. The screw fixing 36 is a fastening means 34 which effects good contact between the current-conducting cooling plate 16 and the printed circuit board 15. In principle, riveted connections may also be expedient; however these effect poor detachability of the printed circuit boards 15 in the event of damage. However, snap connections analogous to a quick release clamp of a bicycle saddle can effect an expedient fastening of the printed circuit board to the cooling plate with a likewise good contact.

In FIGS. 7 to 9, equally large cross-sectional areas are respectively illustrated for the sub-segments 16-1 and 16-2. However, this is not absolutely necessary. It is advantageous if both sub-segments 16-1 and 16-2 are attached to a heat sink 38. In FIGS. 8 and 9, the heat sink 38 is configured in the form of cooling conduits 40. A heat sink can, however, also be a physical contact with another good thermal conductor, which conducts the heat from the cooling plate 16 away and out of the motor 10. A heat sink 38 can also be a sufficient distance between the cooling plates 16, through which a fluid, in particular air, flows.

In FIGS. 8 and 9, possible configurations for the arrangement of cooling conduits 40 through the cooling plate 16 are provided. In FIG. 8, the cooling conduit 40 is inserted into grooves in the cooling surface 22. The cooling conduits 40 of FIG. 8 have a rectangular cross section by way of example.

In FIG. 9, cooling conduits 40 are likewise introduced into the cooling plate 16 but are located in the center of the cooling plate 16. Cooling conduits 40 of this type can be produced either by a sand casting process with a lost core, in particular of aluminum sand-casting. Alternatively, the cooling plate can also be divided in a horizontal plane 42, so that there the cooling conduits are likewise cut out in the form of grooves which, when the horizontally divided cooling plate 16 is joined together, result in a closed cooling conduit 40. The horizontally divided cooling plates can then be joined together by means of a soldering process during production or sealed off by circumferential seals. The second alternative would make it possible to create further sub-segments (not illustrated), which could provide a further independent current-conducting potential.

The advantage of the electric motor 10 described and the arrangement described of the power electronics on cooling plates 16 and printed circuit boards 15 consists in the fact that the cooling plate 16 which is also used in the prior art to carry heat away from the power electronics components is simultaneously used for making their electrical contact. This firstly has the advantage that no additional components in the form of current-conducting rails are needed which, secondly, do not have to be elaborately arranged to be electrically insulated from cooling conduits. In addition, these current-conducting rails are not located above the printed circuit boards 15 (viewed from the direction of view of the cooling plate 16), so that in the event of a defect in a printed circuit board 15, not all the contacts of the further printed circuit boards 15 have to be removed. The arrangement described therefore requires less effort in terms of assembly and fewer parts both for initial assembly of the electric motor 10 and in the event of a possible repair.

### REFERENCE SIGNS

8 Stator/rotor block
9 Motor axis
10 Electric motor
11 Stator
12 Conductor bars
13 Front face
14 Rear side
15 Printed circuit boards
16 Cooling plate
16-1 First sub-segment of cooling plate
16-2 Second sub-segment of cooling plate
17 Shoe
18 Connecting element
20 Separation surface
22 Cooling surface
24 Contact points
26 Semiconductor switches
28 Screw fixing
30 Insulation
32 Busbar of the prior art
34 Fastening means
36 Screw fixing
38 Heat sink
40 Cooling conduit
42 Horizontal plane

1.-12. (canceled)

13. An electric motor, comprising;
a stator comprising a plurality of bar-shaped field conductors;
a cooling plate arranged such that the field conductors are mechanically operatively connected to the cooling plate via current conductors that are electrically connected to the field conductors, said cooling plate being segmented into at least two sub-segments, which are electrically insulated from one another and annular or designed in a form of annular sectors, wherein a separating surface between the sub-segments represents less than 20% of a cooling surface;
a printed circuit board structure comprising one or more printed circuit boards, at least one of the printed circuit boards being arranged on the cooling plate, wherein the printed circuit boards are electrically contacted to the sub-segments of the cooling plate in order to supply power; and
a plurality of power electronics components designed to control the field conductors and arranged on the printed circuit board structure.

14. The electric motor of claim 13, further comprising fasteners designed to realize a contacting of the at least one of the printed circuit boards on the cooling plate at contact points.

15. The electric motor of claim 14, wherein the fasteners are screws.

16. The electric motor of claim 13, further comprising a heat sink, said cooling plate being thermally connected to the heat sink.

17. The electric motor of claim 16, wherein the heatsink is designed in a form of a cooling conduit.

18. The electric motor of claim 17, wherein the cooling conduit runs through the cooling plate in a horizontal plane.

19. The electric motor of claim 13, wherein the cooling plate is formed from aluminum or copper or from an alloy of aluminum or copper.

20. The electric motor of claim 13, wherein the printed circuit boards are designed in a form of a circle or an annular sector.

21. The electric motor of claim 13, wherein the cooling plate is arranged at a right angle to an axis of the electric motor.
